(19) United States
(12) Patent Application Publication
(10) Pub. No.: US 2023/0288468 A1
(43) Pub. Date: Sep. 14, 2023

(54) SENSOR CIRCUIT AND ELECTRONIC EQUIPMENT

(71) Applicant: Mitsubishi Electric Corporation, Tokyo (JP)

(72) Inventors: Akihito KOBAYASHI, Tokyo (JP); Kenji HIROSE, Tokyo (JP)

(73) Assignee: Mitsubishi Electric Corporation, Tokyo (JP)

(21) Appl. No.: 18/197,285

(22) Filed: May 15, 2023

Related U.S. Application Data
(63) Continuation of application No. PCT/JP2021/003441, filed on Feb. 1, 2021.

(51) Int. Cl. G01R 29/26; H02M 1/00; H02M 7/539

(52) U.S. Cl. CPC G01R 29/26; H02M 1/0009; H02M 7/539; H02P 27/08

(57) ABSTRACT

Disclosed is a sensor circuit including a resistance for detection connected to a wire, a first terminal pair comprised of terminal wires connected respectively to terminals of the resistance for detection, a second terminal pair comprised of terminal wires short-circuited to each other at one terminal of the resistance for detection, and a sensing section to measure a current or voltage from which a noise component is removed using a detection signal inputted thereto via the first terminal pair and a detection signal inputted thereto via the second terminal pair.

### CROSS REFERENCE TO RELATED APPLICATIONS

This application is a Continuation of PCT International Application No. PCT/JP2021/003441, filed on Feb. 1, 2021, which is hereby expressly incorporated by reference into the present application.

### TECHNICAL FIELD

The present disclosure relates to a sensor circuit and electronic equipment.

### BACKGROUND ART

The rejection of common mode noises in a differential device is expressed quantitatively using a common mode rejection ratio (referred to as a CMRR hereinafter). As a conventional technique for improving the CMRR, there is, for example, a differential probe described in Patent Literature 1. A common mode choke coil (referred to as a CMC hereinafter) is connected to a pair of contact terminals included in the differential probe. The CMC has high impedance for common mode noises, thereby reducing common mode noises flowing into the differential probe.

### CITATION LIST

### Patent Literature

Patent Literature 1: JP H07-12871

### SUMMARY OF INVENTION

### Technical Problem

The differential probe described in Patent Literature 1 is a sensor circuit including the CMC, and a parasitic capacitance occurs unavoidably at both ends of the coil winding in the CMC. Because the parasitic capacitance occurring in the CMC reduces the impedance of the CMC for a common mode noise having a high frequency, a problem is that the common mode noise reduces the accuracy of measurement in a high frequency range.

The present disclosure is made to solve the above-mentioned problem, and it is therefore an object of the present disclosure to obtain a sensor circuit that can remove an error caused by a noise component from a measured value of a current or voltage in a wire connecting a drive circuit and a load circuit which are included electronic equipment, and electronic equipment including the sensor circuit.

### Solution to Problem

A sensor circuit according to the present disclosure measures a current or voltage in a wire of electronic equipment having a circuit section in which a drive circuit and a load circuit are connected by one or multiple wires, the sensor circuit including: a resistance for detection connected to the one or multiple wires; a first terminal pair comprised of terminal wires connected respectively to the terminals of the resistance for detection; a second terminal pair comprised of terminal wires short-circuited to each other at one terminal of the resistance for detection; and a sensing circuit to measure the current or voltage from which a noise component is removed using a detection signal inputted thereto via the first terminal pair and a detection signal inputted thereto via the second terminal pair.

### Advantageous Effects of Invention

According to the present disclosure, on a detection signal inputted via a first terminal pair is superimposed a common mode noise component in addition to a differential component which is a true value of a current or voltage in one or multiple wires. Because a second terminal pair is short-circuited to each other at one terminal of a resistance for detection, only a common mode noise component which is an error is contained in a detection signal inputted via the second terminal pair. As a result, by subtracting the noise component inputted via the second terminal pair from the detection signal inputted via the first terminal pair, the sensor circuit according to the present disclosure can remove the error caused by the noise component from a measured value of the current or voltage in the one or multiple wires connecting a drive circuit and a load circuit which are included in electronic equipment.

### BRIEF DESCRIPTION OF DRAWINGS

FIG. 1 is a block diagram showing an example of the configuration of electronic equipment according to Embodiment 1;

FIG. 2 is a block diagram showing the configuration of a variant of a sensor circuit;

FIG. 3 is a block diagram showing an example of the configuration of a sensing section;

FIG. 4 is an explanatory drawing showing an overview of a noise correction performed by the sensing section;

FIG. 5 is a block diagram showing the configuration of a variant of the sensor section;

FIG. 6 is a block diagram showing an example of the configuration of electronic equipment according to Embodiment 2;

FIG. 7 is a block diagram showing the configuration of a variant of a sensor circuit;

FIG. 8 is a block diagram showing the configuration of a variant (1) of the electronic equipment according to Embodiment 2; and

FIG. 9 is a block diagram showing the configuration of a variant (2) of the electronic equipment according to Embodiment 2.

### DESCRIPTION OF EMBODIMENTS

### Embodiment 1

FIG. 1 is a block diagram showing an example of the configuration of electronic equipment 1 according to Embodiment 1. In FIG. 1, the electronic equipment 1 includes a circuit section 2, a sensor circuit 3, and a control unit 4. The circuit section 2 includes a drive circuit 21 and a load circuit 22, and the drive circuit 21 and the load circuit 22 are electrically connected by a wire 23. The drive circuit 21 drives the load circuit 22 and applies a voltage Vs to the wire 23. The load circuit 22 has an impedance Z_{L} and is driven by the drive circuit 21. The circuit section 2 is coupled to a reference GND having a ground potential by a parasitic capacitance C_{P}. The circuit section 2 is formed with a loop path containing the parasitic capacitance C_{P}, and a common mode noise having a voltage Vc is present in this loop path.

The sensor circuit 3 measures a current or voltage which the drive circuit 21 supplies to the load circuit 22 via the wire 23. More specifically, the sensor circuit 3 measures the current or voltage in the wire 23. The sensor circuit 3 includes a first resistor for detection R_{S_1} and a second resistor for detection R_{S_2}, each of which is a resistance for detection connected to the wire 23, a first terminal pair 31, a second terminal pair 32, and a sensing section 33. The first resistor for detection R_{S_1} and the second resistor for detection R_{S_2} constitute a series resistance circuit connected in two series in the wire 23. Further, the first resistor for detection R_{S_1} and the second resistor for detection R_{S_2} are resistive elements having the same resistance value Rs.

The first terminal pair 31 is constituted by terminal wires connected respectively to terminals 34 and 35 of the resistance for detection. In FIG. 1, the first terminal pair 31 is constituted by a terminal wire connected to the terminal 34 in the first resistor for detection R_{S_1} of the above-mentioned series resistance circuit, the terminal 34 being opposite to the second resistor for detection R_{S_2}, and a terminal wire connected to the terminal 35 in the second resistor for detection R_{S_2} of the series resistance circuit, the terminal 35 being opposite to the first resistor for detection R_{S_1}.

The second terminal pair 32 is constituted by two terminal wires short-circuited to each other at one terminal 36 of the resistance for detection. In FIG. 1, the two terminal wires which constitute the second terminal pair 32 are connected to each other and short-circuited at the terminal 36 where the first resistor for detection R_{S_1} and the second resistor for detection R_{S_2} in the series resistance circuit are connected.

The sensing section 33 measures the current or voltage from which a noise component in the wire 23 is removed using a detection signal inputted thereto via the first terminal pair 31 and a detection signal inputted thereto via the second terminal pair 32. Measurement data about the current or voltage measured by the sensing section 33 is outputted to the control unit 4. The electronic equipment 1 includes components other than the components shown in FIG. 1. The control unit 4 controls the operations of the components on the basis of the measured value of the current or voltage which is measured by the sensor circuit 3 from the circuit section 2.

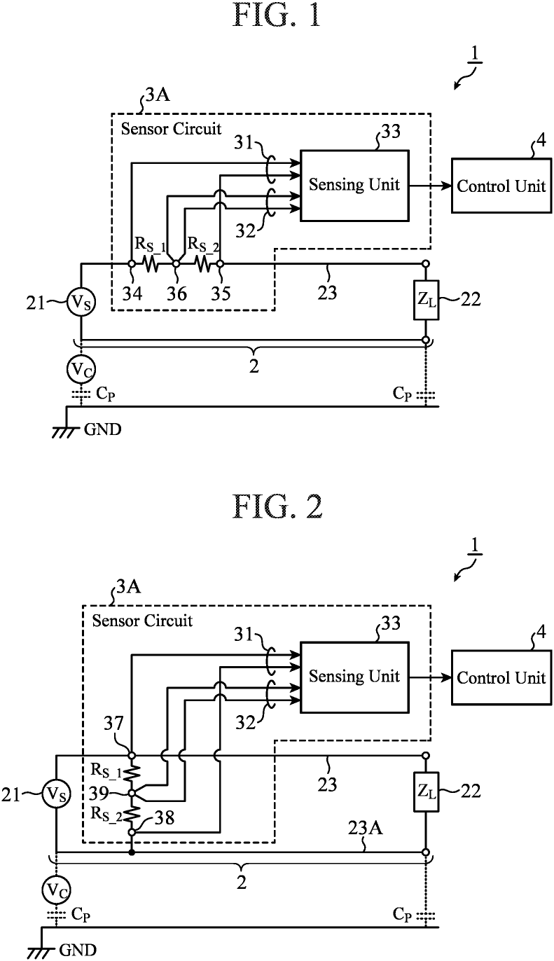

FIG. 2 is a block diagram showing the configuration of a sensor circuit 3A which is a variant of the sensor circuit 3. As shown in FIG. 2, a resistance for detection which is included in the sensor circuit 3A is a series resistance circuit in which a first resistor for detection R_{S_1} and a second resistor for detection R_{S_2} are connected between a wire 23 and a wire 23A and in series to the wire 23. The wire 23A is the one which is coupled to a reference GND having a ground potential by a parasitic capacitance C_{P}, out of the wires connecting a drive circuit 21 and a load circuit 22. In the resistance for detection configured in this way, the first terminal pair 31 is constituted by terminal wires connected respectively to terminals 37 and 38 of the series resistance circuit, and the second terminal pair 32 is constituted by two terminal wires short-circuited at a terminal 39 where the first resistor for detection R_{S_1} and the second resistor for detection R_{S_2} in the series resistance circuit are connected, as shown in FIG. 2.

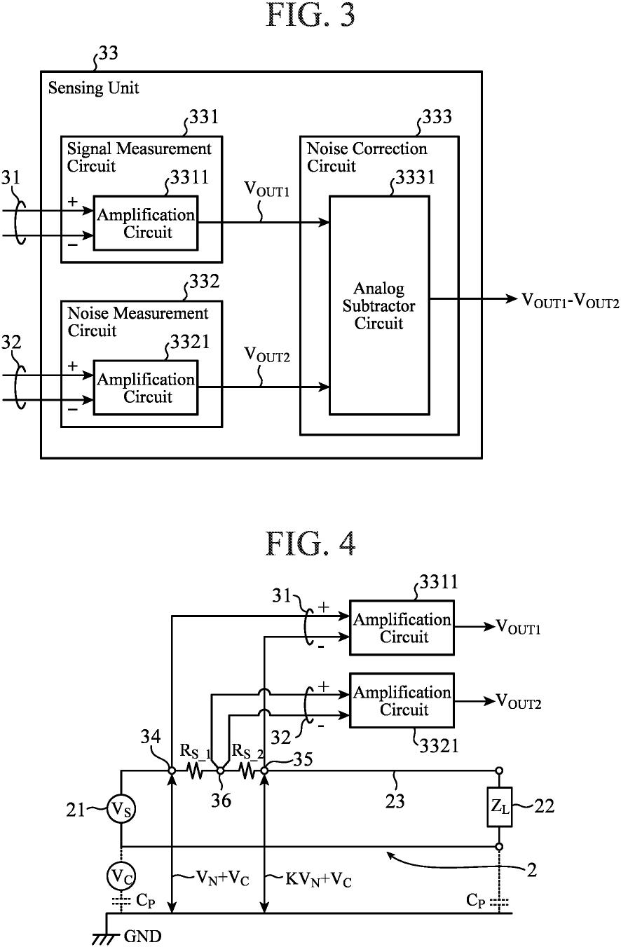

FIG. 3 is a block diagram showing an example of the configuration of the sensing section 33. As shown in FIG. 3, the sensing section 33 includes a signal measurement circuit 331, a noise measurement circuit 332, and a noise correction circuit 333. The signal measurement circuit 331 and the noise measurement circuit 332 are the same in circuit configuration as each other. The signal measurement circuit 331 includes an amplification circuit 3311, and amplifies the detection signal of the current or voltage containing the noise component, the detection signal being inputted thereto via the first terminal pair 31. In FIG. 3, the amplification circuit 3311 amplifies the detection signal inputted thereto via the first terminal pair 31, and outputs the amplified signal (voltage V_{OUT1}) to the noise correction circuit 333.

The noise measurement circuit 332 includes an amplification circuit 3321, and amplifies the detection signal containing only the noise component, the detection signal being inputted thereto via the second terminal pair 32. In FIG. 3, the amplification circuit 3321 amplifies the detection signal inputted thereto via the second terminal pair 32, and outputs the amplified signal (voltage V_{OUT2}) to the noise correction circuit 333. The amplification circuit 3311 and the amplification circuit 3321 are constituted by, for example, inverting or non-inverting amplifier circuits each of which employs an operational amplifier.

The noise correction circuit 333 includes an analog subtractor circuit 3331, and subtracts the value of the detection signal amplified by the noise measurement circuit 332 from the value of the detection signal amplified by the signal measurement circuit 331. The analog subtractor circuit 3331 outputs an analog signal having a voltage V_{OUT1}-V_{OUT2} to the control unit 4 by subtracting the voltage V_{OUT2} inputted thereto from the noise measurement circuit 332 from the voltage V_{OUT1} inputted thereto from the signal measurement circuit 331. The analog subtractor circuit 3331 is constituted by, for example, a subtractor circuit which employs an operational amplifier.

Further, the first terminal pair 31 and the second terminal pair 32 are equal in wire length of the terminal wire to each other. For example, in a case where the first terminal pair 31 is constituted by a terminal wire (1) which connects the terminal 34 and a positive terminal (+) of the amplification circuit 3311, and a terminal wire (2) which connects the terminal 35 and a negative terminal (-) of the amplification circuit 3311, and the second terminal pair 32 is constituted by a terminal wire (3) and a terminal wire (4) which are short-circuited by the terminal 36, the terminal wires (1) to (4) are equal in wire length to each other.

FIG. 4 is an explanatory drawing showing an overview of a noise correction performed by the sensing section 33. As shown in FIG. 4, the positive terminal (+) in the first terminal pair 31 is connected to the terminal 34 in the wire 23, and the negative terminal (-) in the first terminal pair 31 is connected to the terminal 35 in the wire 23. The electric potential V_{P} of the terminal 34 with respect to the reference GND which is the ground potential is expressed by the following equation (1). In the following equation (1), Vs is the voltage applied to the wire 23 by the drive circuit 21, and Vc is the voltage of the common mode noise.

$${\text{V}}_{\text{P}} = {\text{V}}_{\text{S}} + {\text{V}}_{\text{C}} \qquad \text{(1)}$$

Further, the electric potential V_{N} of the terminal 35 with respect to the reference GND which is the ground potential is expressed by the following equation (2). In the following equation (2), K is a variable.

$${\text{V}}_{\text{N}} = \text{K} ⋅ {\text{V}}_{\text{S}} + {\text{V}}_{\text{C}} \qquad \text{(2)}$$

The variable K in the above-mentioned equation (2) is expressed by the following equation (3) using the impedance Z_{L} of the load circuit 22, the resistance value R_{S} of the first resistor for detection R_{S_1}, and the resistance value R_{S} of the second resistor for detection R_{S_2}.

$$\text{K} = {\text{Z}}_{\text{L}} / \left(2 ⋅ {\text{R}}_{\text{S}} + {\text{Z}}_{\text{L}}\right) \qquad \text{(3)}$$

A differential mode voltage V_{DIFF} which is inputted to the amplification circuit 3311 via the first terminal pair 31 and which contains the voltage value of a common mode noise component is expressed by the following equation (4).

$${\text{V}}_{\text{D} \text{I} \text{F} \text{F}} = {\text{V}}_{\text{P}} - {\text{V}}_{\text{N}} = \left(1 - \text{K}\right) ⋅ {\text{V}}_{\text{S}} \qquad \text{(4)}$$

Further, a common mode voltage V_{COM} which is inputted to the amplification circuit 3321 via the second terminal pair 32 and which is the voltage of the common mode noise component is expressed by the following equation (5).

$${\text{V}}_{\text{COM}} = \left({\text{V}}_{\text{P}} + {\text{V}}_{\text{N}}\right) / 2 = \left\{\left(1 + \text{K}\right) / 2\right\} ⋅ {\text{V}}_{\text{S}} + {\text{V}}_{\text{C}} \qquad \text{(5)}$$

When the reference potential is the ground potential, the output voltage V_{OUT1} of the signal amplified by the amplification circuit 3311 is expressed by the following equation (6) using a differential gain A_{D}, a common mode gain Ac, the differential mode voltage V_{DIFF}, the common mode voltage V_{COM}, and the variable K. When the common mode voltage V_{COM} is amplified depending on the common mode gain Ac, the accuracy of measurement of the voltage V_{OUT1} between the terminals of the resistance for detection degrades because of a relation shown by the following equation (6).

$$\begin{matrix}{\text{V}}_{\text{OUT1}} = {\text{A}}_{\text{D}} ⋅ {\text{V}}_{\text{DIFF}} + {\text{A}}_{\text{C}} ⋅ {\text{V}}_{\text{COM}} = {\text{A}}_{\text{D}} ⋅ \left(1 - \text{K}\right) ⋅ {\text{V}}_{\text{S}} + {\text{A}}_{\text{C}} ⋅ \\ \left[\left\{\left(1 + \text{K}\right) / 2\right\} ⋅ {\text{V}}_{\text{S}} + {\text{V}}_{\text{C}}\right]\end{matrix} \qquad \text{(6)}$$

The positive terminal (+) and the negative terminal (-) in the second terminal pair 32 are short-circuited at the terminal 36. The electric potential V_{M} of the terminal 36 with respect to the ground potential is expressed by the following equation (7).

$${\text{V}}_{\text{M}} = \left\{\left(1 + \text{K}\right) / 2\right\} ⋅ {\text{V}}_{\text{S}} + {\text{V}}_{\text{C}} \qquad \text{(7)}$$

In the output voltage V_{OUT2} of the signal amplified by the amplification circuit 3321, the differential mode voltage V_{DIFF} which is a differential component is 0 (V), and only the common mode voltage V_{COM} expressed by the above-mentioned equation (5) is contained as the noise component. Therefore, the output voltage V_{OUT2} is expressed by the following equation (8). Because the amplification circuit 3321 and the amplification circuit 3311 are the same in circuit configuration as each other, the differential gain A_{D} and the common mode gain A_{C} are equal in value to each other in the amplification circuit 3321 and in the amplification circuit 3311.

$$\begin{matrix}{\text{V}}_{\text{OUT2}} = {\text{A}}_{\text{D}} ⋅ {\text{V}}_{\text{DIFF}} + {\text{A}}_{\text{C}} ⋅ {\text{V}}_{\text{COM}} \\ = {\text{A}}_{\text{C}} ⋅ \left[\left\{\left(1 + \text{K}\right) / 2\right\} ⋅ {\text{V}}_{\text{S}} + {\text{V}}_{\text{C}}\right]\end{matrix} \qquad \text{(8)}$$

The analog subtractor circuit 3331 outputs a signal having an output voltage V_{OUT3} expressed by the following equation (9) to the control unit 4 by subtracting the output voltage V_{OUT2} expressed by the above-mentioned equation (8) from the output voltage V_{OUT1} expressed by the above-mentioned equation (6).

$${\text{V}}_{\text{OUT3}} = {\text{V}}_{\text{OUT1}} - {\text{V}}_{\text{OUT2}} = {\text{A}}_{\text{D}} ⋅ \left(1 - \text{K}\right) ⋅ {\text{V}}_{\text{S}} \qquad \text{(9)}$$

As is clear from the above equation (9), the component having the common mode voltage V_{COM} amplified with the common mode gain A_{C} is removed from the output voltage V_{OUT3} of the sensing section 33 in comparison with the output voltage V_{OUT1} expressed by the above-mentioned equation (6), and the accuracy of sensing is improved.

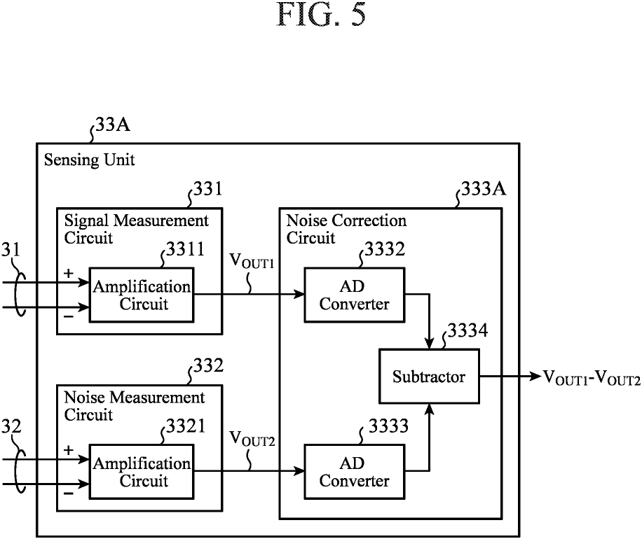

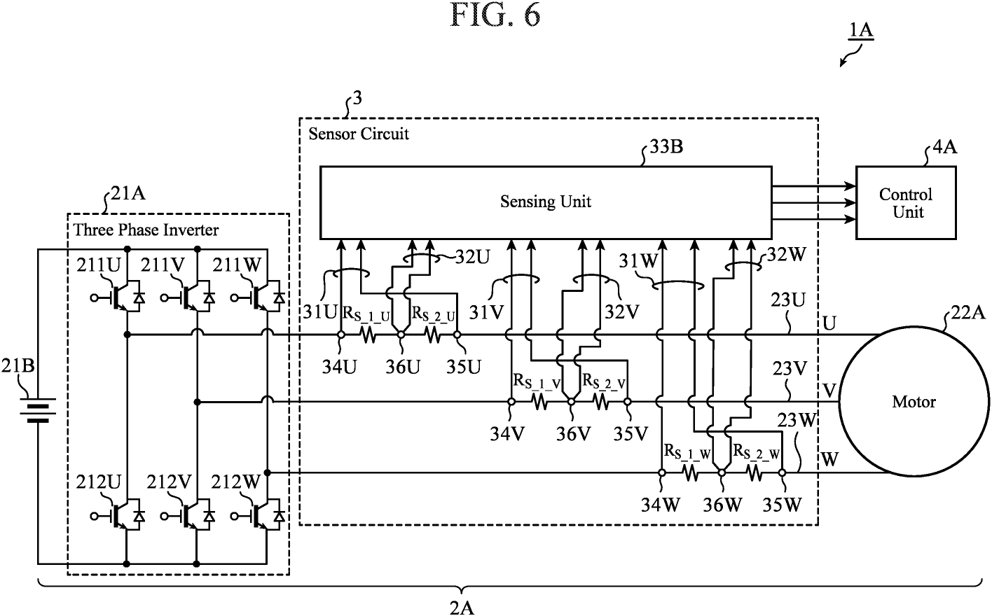

FIG. 5 is a block diagram showing the configuration of a sensing section 33A which is a variant of the sensing section 33. In FIG. 5, the same components as those in FIG. 3 are denoted by the same reference signs. The sensing section 33A includes a signal measurement circuit 331, a noise measurement circuit 332, and a noise correction circuit 333A. The signal measurement circuit 331 and the noise measurement circuit 332 are the same in circuit configuration as each other. The noise correction circuit 333A includes an AD converter 3332, an AD converter 3333, and a subtractor 3334.

The AD converter 3332 converts a detection signal amplified by the signal measurement circuit 331 into a digital signal, and outputs the digital signal to the subtractor 3334. The AD converter 3333 converts a detection signal amplified by the noise measurement circuit 332 into a digital signal, and outputs the digital signal to the subtractor 3334. The subtractor 3334 subtracts the digital signal showing a voltage V_{OUT2} from the digital signal showing a voltage V_{OUT1}, thereby outputting a digital signal showing a voltage V_{OUT1}-V_{OUT2} to the control unit 4.

A filtering process may be performed on the digital signal converted by the AD converter 3332 and the digital signal converted by the AD converter 3333 before the digital signals are outputted to the subtractor 3334. For example, a filtering process of removing noise components other than differential components and common mode noise components from the digital signals are performed. The subtractor 3334 performs a subtraction on the digital signals after the filtering process.

In the sensor circuit 3 or 3A, the resistance for detection is not limited to the one constituted by the two resistors: the first resistor for detection R_{S_1} and the second resistor for detection R_{S_2}, and the resistance for detection may be a single resistive element or a resistance circuit which is a combination of three or more resistive elements.

In a case where the electronic equipment 1 includes multiple circuit sections 2, the sensor circuit 3 or 3A may include a resistance for detection, a first terminal pair, and a second terminal pair for each of the multiple circuit sections 2. In this case, the sensor circuit 3 or 3A can simultaneously perform measurements on the multiple circuit sections 2.

Further, the sensing section 33 or 33A may be a discrete part independent of the control unit 4, or the sensing section 33 or 33A and the control unit 4 may be a single integrated circuit (IC).

In a case where the wire 23 is a high speed signal one, the sensor circuit 3 or 3A measures the current or voltage in the high speed signal wire. In this case, the control unit 4 performs a signal analysis in the high speed signal wire using a signal showing the current or voltage measured by the sensor circuit 3 or 3A.

As mentioned above, the sensor circuit 3 or 3A according to Embodiment 1 includes: the resistance for detection connected to the wire 23; the first terminal pair 31 constituted by the terminal wires connected respectively to the terminals of the resistance for detection; the second terminal pair 32 constituted by the terminal wires short-circuited to each other at one terminal of the resistance for detection; and the sensing section 33 to measure the current or voltage from which a noise component is removed using the detection signal inputted thereto via the first terminal pair 31 and the detection signal inputted thereto via the second terminal pair 32. On the detection signal inputted via the first terminal pair 31 is superimposed a common mode noise component in addition to a differential component which is a true value of the current or voltage in the wire. Because the second terminal pair 32 is mutually short-circuited at the one terminal of the resistance for detection, only a common mode noise component is contained in the detection signal inputted via the second terminal pair 32. As a result, the sensor circuit 3 or 3A subtracts the noise component inputted thereto via the second terminal pair 32 from the detection signal inputted thereto via the first terminal pair 31, thereby being able to remove an error caused by the noise component from the measured value of the current or voltage in the wire 23.

In the sensor circuit 3 or 3A according to Embodiment 1, the sensing section 33 or 33A includes: the signal measurement circuit 331 to amplify the detection signal inputted thereto via the first terminal pair 31; the noise measurement circuit 332 to amplify the detection signal inputted thereto via the second terminal pair 32; and the noise correction circuit 333 to subtract the value of the detection signal amplified by the noise measurement circuit 332 from the value of the detection signal amplified by the signal measurement circuit 331, and to perform output, and the signal measurement circuit 331 and the noise measurement circuit 332 are the same in circuit configuration as each other. With this configuration, the sensor circuit 3 can properly subtract the noise component inputted thereto via the second terminal pair 32 from the detection signal inputted thereto via the first terminal pair 31.

In the sensor circuit 3 according to Embodiment 1, the resistance for detection is a series resistance circuit constituted by the first resistor for detection R_{S_1} and the second resistor for detection R_{S_2} which are connected in series in the wire 23. The first terminal pair 31 is constituted by the terminal wires connected respectively to the terminals 34 and 35 of the series resistance circuit. The second terminal pair 32 is constituted by the terminal wires short-circuited to each other at the terminal 36 where the first resistor for detection R_{S_1} and the second resistor for detection R_{S_2} in the series resistance circuit are connected. With this configuration, the sensor circuit 3 can properly subtract the noise component inputted thereto via the second terminal pair 32 from the detection signal inputted thereto via the first terminal pair 31.

In the sensor circuit 3A according to Embodiment 1, the resistance for detection is a series resistance circuit constituted by the first resistor for detection R_{S_1} and the second resistor for detection R_{S_2} which are connected in series between the wire 23 and the wire 23A. The first terminal pair 31 is constituted by the terminal wires connected respectively to the terminals 37 and 38 of the series resistance circuit. The second terminal pair 32 is constituted by the terminal wires short-circuited to each other at the terminal 39 which is a point of connection between the first resistor for detection R_{S_1} and the second resistor for detection R_{S_2} in the series resistance circuit. With this configuration, it is possible to properly subtract the noise component inputted via the second terminal pair 32 from the detection signal inputted via the first terminal pair 31.

In the sensor circuit 3 or 3A according to Embodiment 1, the first resistor for detection R_{S_1} and the second resistor for detection R_{S_2} are equal in resistance value to each other. As a result, the sensor circuit 3 can properly subtract the noise component inputted thereto via the second terminal pair 32 from the detection signal inputted thereto via the first terminal pair 31.

In the sensor circuit 3 or 3A according to Embodiment 1, the first resistor for detection R_{S_1} and the second resistor for detection R_{S_2} are equal in wire length of the terminal wire to each other. As a result, the sensor circuit 3 can properly subtract the noise component inputted thereto via the second terminal pair 32 from the detection signal inputted thereto via the first terminal pair 31.

### Embodiment 2

FIG. 6 is a block diagram showing an example of the configuration of electronic equipment 1A according to Embodiment 2. In FIG. 6, the electronic equipment 1A includes a circuit section 2A, a sensor circuit 3, and a control unit 4A. The circuit section 2A includes a three-phase inverter circuit 21A which is a drive circuit, and a three-phase motor 22A which is a load circuit, and the inverter circuit 21A and the motor 22A are electrically connected by wires 23U, 23V, and 23W.

To the inverter circuit 21A is applied a DC voltage by a DC power supply 21B. To a DC input positive terminal of the inverter circuit 21A is connected a positive terminal (+) of the DC power supply 21B, and to a DC input negative terminal of the inverter circuit is connected a negative terminal (-) of the DC power supply 21B. Further, the wires 23U, 23V, and 23W are output ones for outputting currents from the inverter circuit 21A to the motor 22A. The wires 23U, 23V, and 23W may be a wiring pattern formed on a printed circuit board or conductor cables.

Further, the inverter circuit 21A includes an upper arm switching element which is a switching element which constitutes an upper arm, and a lower arm switching element which is a switching element which constitutes a lower arm for each of phases U, V, and W. The DC input positive terminal of the above-mentioned inverter circuit 21A is an input terminal on an upper arm’s side, and the DC input negative terminal of the inverter circuit 21A is an input terminal on a lower arm’s side.

The upper arm switching element and the lower arm switching element of each phase are connected in series. The wires 23U, 23V, and 23W which are the output wires of each phase is connected respectively to points of connection between them. The inverter circuit 21A supplies currents to the three-phase motor 22A via the wires 23U, 23V, and 23W to drive the three-phase motor by switching the upper arm switching elements and the lower arm switching elements.

The sensor circuit 3 measures the values of the currents supplied from the three-phase inverter circuit 21A to the three-phase motor 22A. A signal showing the current value of each phase measured by the sensor circuit 3 is outputted to the control unit 4A. The control unit 4A performs feedback control of the driving of the three-phase motor 22A. For example, the control unit 4A controls the driving of the three-phase motor 22A by performing switching control on the upper arm switching elements and the lower arm switching elements on the basis of the current value of each phase measured by the sensor circuit 3. The control unit 4A performs the switching control using, for example, pulse width modulation (PWM) control.

The sensor circuit 3 includes a resistance for detection, a first terminal pair, and a second terminal pair for each phase, and further includes a sensing section 33B. More specifically, the sensor circuit 3 includes a first resistor for detection R_{S_1_U} and a second resistor for detection R_{S_2_U} which are connected to the wire 23U, a first terminal pair 31U, and a second terminal pair 32U, also includes a first resistor for detection R_{S_1_V} and a second resistor for detection R_{S_2_V} which are connected to the wire 23V, a first terminal pair 31V, and a second terminal pair 32V, and further includes a first resistor for detection R_{S_1_W} and a second resistor for detection R_{S_2_W} which are connected to the wire 23W, a first terminal pair 31W, and a second terminal pair 32W.

The first resistor for detection R_{S_1_U} and the second resistor for detection R_{S_2_U} constitute a series resistance circuit connected in two series to the wire 23U. The first resistor for detection R_{S_1_V} and the second resistor for detection R_{S_2_V} constitute a series resistance circuit connected in two series to the wire 23V. The first resistor for detection R_{S_1_W} and the second resistor for detection R_{S_2_W} constitute a series resistance circuit connected in two series to the wire 23W.

The first terminal pair 31U is constituted by a terminal wire connected to a terminal 34U in the first resistor for detection R_{S_1_U} of the series resistance circuit, the terminal 34U being opposite to the second resistor for detection R_{S_2_U}, and a terminal wire connected to a terminal 35U in the second resistor for detection R_{S_2_U} of the series resistance circuit, the terminal 35U being opposite to the first resistor for detection R_{S_1_U}. The second terminal pair 32U is constituted by two terminal wires which are connected to each other and short-circuited at a terminal 36U where the first resistor for detection R_{S_1_U} and the second resistor for detection R_{S_2_U} are connected.

The first terminal pair 31V is constituted by a terminal wire connected to a terminal 34V in the first resistor for detection R_{S_1_V} of the series resistance circuit, the terminal 34V being opposite to the second resistor for detection R_{S_2_V}, and a terminal wire connected to a terminal 35V in the second resistor for detection R_{S_2_V} of the series resistance circuit, the terminal 35V being opposite to the first resistor for detection R_{S_1_V}. The second terminal pair 32V is constituted by two terminal wires which are connected to each other and short-circuited at a terminal 36V where the first resistor for detection R_{S_1_V} and the second resistor for detection R_{S_2_V} are connected.

The first terminal pair 31W is constituted by a terminal wire connected to a terminal 34W in the first resistor for detection R_{S_1_W} of the series resistance circuit, the terminal 34W being opposite to the second resistor for detection R_{S_2_W}, and a terminal wire connected to a terminal 35W in the second resistor for detection R_{S_2_W} of the series resistance circuit, the terminal 35W being opposite to the first resistor for detection R_{S_1_W}. The second terminal pair 32W is constituted by two terminal wires which are connected to each other and short-circuited at a terminal 36W where the first resistor for detection R_{S_1_W} and the second resistor for detection R_{S_2_W} are connected.

The sensing section 33B includes, for example, a signal measurement circuit 331, a noise measurement circuit 332, and a noise correction circuit 333, like the sensing section shown in Embodiment 1. Also in the sensing section 33B, the signal measurement circuit 331 and the noise measurement circuit 332 are the same in circuit configuration as each other. The signal measurement circuit 331 also includes an amplification circuit 3311, and amplifies each of detection signals of the currents, the detection signals being inputted via the first terminal pairs 31U, 31V, and 31W, and containing noise components. The amplification circuit 3311 amplifies each of the detection signals inputted thereto via the first terminal pairs 31U, 31V, and 31W, and outputs the signal of each phase amplified thereby to the noise correction circuit 333.

The noise measurement circuit 332 includes an amplification circuit 3321, and amplifies each of detection signals inputted via the second terminal pairs 32U, 32V, and 32W, and containing only the noise components. The amplification circuit 3321 amplifies each of the detection signals inputted thereto via the second terminal pairs 32U, 32V, and 32W, and outputs the signal of each phase amplified thereby to the noise correction circuit 333. The amplification circuit 3311 and the amplification circuit 3321 are constituted by inverting amplifier circuits or non-inverting amplifier circuits each of which employs, for example, an operational amplifier.

The noise correction circuit 333 includes an analog subtractor circuit 3331, and subtracts the value of the detection signal of each phase amplified by the noise measurement circuit 332 from the value of the detection signal of each phase amplified by the signal measurement circuit 331. An analog signal showing the current value of each phase subtracted by the analog subtractor circuit 3331 is outputted to the control unit 4A. In the signal showing the current of each phase outputted from the sensing section 33B to the control unit 4A, a common mode noise component amplified with a common mode gain is removed. As a result, the sensor circuit 3 provides an improvement in the sensing accuracy of the currents in the wires 23U, 23V, and 23W.

Further, the sensing section 33B may include a noise correction circuit 333A instead of the noise correction circuit 333. An AD converter 3332 included in the noise correction circuit 333A converts the detection signal of each phase amplified by the signal measurement circuit 331 into a digital signal, and outputs the digital signal to a subtractor 3334 for each phase. An AD converter 3333 converts the detection signal of each phase amplified by the noise measurement circuit 332 into a digital signal, and outputs the digital signal to the subtractor 3334 for each phase. The subtractor 3334 subtracts the digital signal of each phase amplified by the noise measurement circuit 332 from the digital signal of each phase amplified by the signal measurement circuit 331, thereby outputting a digital signal which is a subtraction result to the control unit 4A.

The digital signal of each phase converted by the AD converter 3332 and the digital signal of each phase converted by the AD converter 3333 may undergo a filtering process before they are outputted to the subtractor 3334. For example, a filtering process of removing a noise component other than a differential component and the common mode noise component from the digital signal of each phase is performed. The subtractor 3334 performs a subtraction of the digital signal of each phase after the filtering process.

Further, the first terminal pair 31U and the second terminal pair 32U are equal in wire length of the terminal wire to each other. The first terminal pair 31V and the second terminal pair 32V are equal in wire length of the terminal wire to each other. The first terminal pair 31W and the second terminal pair 32W are equal in wire length of the terminal wire to each other. For example, in a case where the first terminal pair 31U is constituted by a terminal wire (1) which connects the terminal 34U and a positive terminal (+) of the amplification circuit 3311, and a terminal wire (2) which connects the terminal 35U and a negative terminal (-) of the amplification circuit 3311, and the second terminal pair 32U is constituted by a terminal wire (3) and a terminal wire (4) which are short-circuited by the terminal 36U, the terminal wires (1) to (4) are equal in wire length to each other. Between the same phases and between different phases, the wire lengths of the terminal wires which constitute the first terminal pair and the second terminal pair are equal to each other.

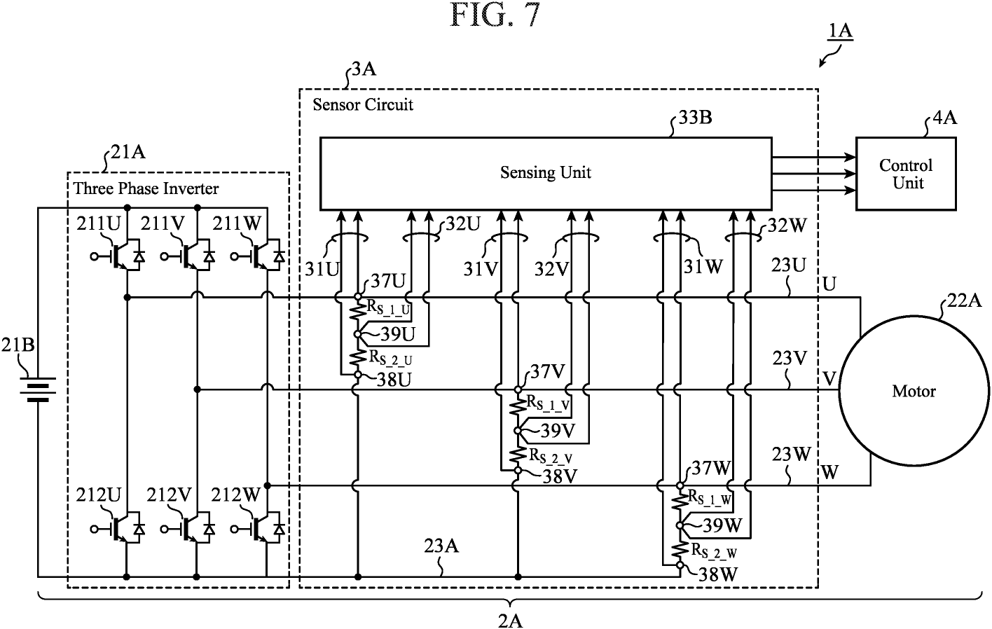

FIG. 7 is a block diagram showing the configuration of a sensor circuit 3A which is a variant of the sensor circuit 3, and shows a resistance for detection in the phase U as an example. As shown in FIG. 7, the resistance for detection which is included in the sensor circuit 3A may be a series resistance circuit in which a first resistor for detection R_{S_1_U} and a second resistor for detection R_{S_2_U} are connected in series between a wire 23U and a wire 23A. Similarly, in the phase V, a resistance for detection is a series resistance circuit in which a first resistor for detection R_{S_1_V} and a second resistor for detection R_{S_2_V} are connected in series between a wire 23V and the wire 23A, and in the phase W, a resistance for detection is a series resistance circuit in which a first resistor for detection R_{S_1_W} and a second resistor for detection R_{S_2_W} are connected in series between a wire 23W and the wire 23A. The wire 23A is connected to a negative terminal (-) of a DC power supply 21B.

A first terminal pair 31U is constituted by terminal wires connected respectively to terminals 37U and 38U of the above-mentioned series resistance circuit. A second terminal pair 32U is constituted by two terminal wires which are short-circuited at a terminal 39U where the first resistor for detection R_{S_1_U} and the second resistor for detection R_{S_2_U} in the above-mentioned series resistance circuit are connected. The same goes for a first terminal pair 31V, a second terminal pair 32V, a first terminal pair 31W, and a second terminal pair 32W.

More specifically, the first terminal pair 31V is constituted by terminal wires connected respectively to terminals 37V and 38V of the above-mentioned series resistance circuit. The second terminal pair 32V is constituted by two terminal wires which are short-circuited at a terminal 39V where the first resistor for detection R_{S_1_V} and the second resistor for detection R_{S_2_V} in the above-mentioned series resistance circuit are connected. The first terminal pair 31W is constituted by terminal wires connected respectively to terminals 37W and 38W of the above-mentioned series resistance circuit. The second terminal pair 32W is constituted by two terminal wires which are short-circuited at a terminal 39W where the first resistor for detection R_{S_1_W} and the second resistor for detection R_{S_2_W} in the above-mentioned series resistance circuit are connected.

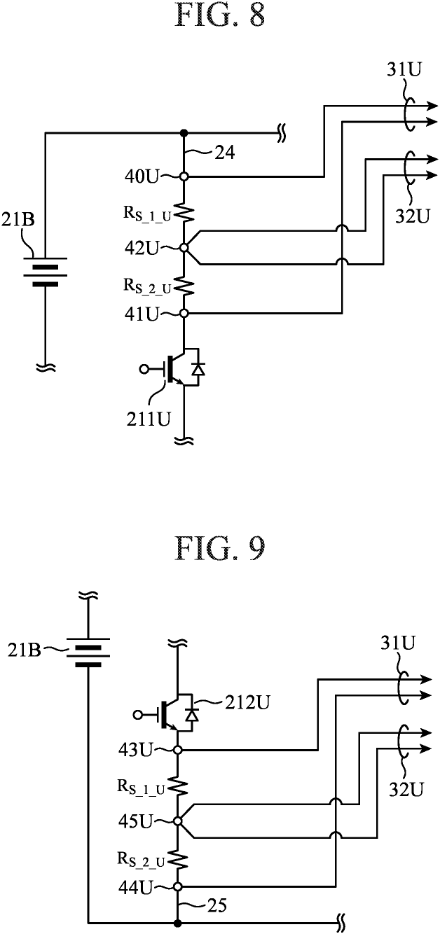

FIG. 8 is a block diagram showing the configuration of a variant (1) of the electronic equipment 1A. In a sensor circuit 3 or 3A, a resistance for detection may be a series resistance circuit in which a first resistor for detection and a second resistor for detection are connected in series with respect to a wire 24 which connects between an upper arm switching element for each phase and a positive terminal (+) of a DC power supply, as shown in FIG. 8.

A first terminal pair 31U is constituted by a terminal wire connected to a terminal 40U in the first resistor for detection R_{S_1_U} of the series resistance circuit, the terminal 40U being opposite to the second resistor for detection R_{S_2_U}, and a terminal wire connected to a terminal 41U in the second resistor for detection R_{S_2_U} of the series resistance circuit, the terminal 41U being opposite to the first resistor for detection R_{S_1_U}. A second terminal pair 32U is constituted by two terminal wires which are connected to each other and short-circuited at a terminal 42U where the first resistor for detection R_{S_1_U} and the second resistor for detection R_{S_2_U} are connected.

The same goes for a first terminal pair 31V, a second terminal pair 32V, a first terminal pair 31W, and a second terminal pair 32W whose representations are omitted in FIG. 8. More specifically, the first terminal pair 31V is constituted by a terminal wire connected to a terminal 40V in a first resistor for detection R_{S_1_V} of a series resistance circuit, the terminal 40V being opposite to a second resistor for detection R_{S_2_V}, and a terminal wire connected to a terminal 41V in the second resistor for detection R_{S_2_V} of the series resistance circuit, the terminal 41V being opposite to the first resistor for detection R_{S_1_V}. The second terminal pair 32V is constituted by two terminal wires which are connected to each other and short-circuited at a terminal 42V where the first resistor for detection R_{S_1_V} and the second resistor for detection R_{S_2_V} are connected.

The first terminal pair 31W is constituted by a terminal wire connected to a terminal 40W in a first resistor for detection R_{S_1_W} of a series resistance circuit, the terminal 40W being opposite to a second resistor for detection R_{S_2_W}, and a terminal wire connected to a terminal 41W in the second resistor for detection R_{S_2_W} of the series resistance circuit, the terminal 41W being opposite to the first resistor for detection R_{S_1_W}. The second terminal pair 32W is constituted by two terminal wires which are connected to each other and short-circuited at a terminal 42W where the first resistor for detection R_{S_1_W} and the second resistor for detection R_{S_2_W} are connected.

A sensing section 33B subtracts detection signals inputted via the second terminal pairs 32U, 32V, and 32W and each containing only a noise component from detection signals of current values inputted thereto via the first terminal pairs 31U, 31V, and 31W and each containing the noise component, thereby removing the noise component (common mode noise component) in the wire 24 of each phase, and measures the current value in the wire 24 of each phase from which the noise component is removed.

The electronic equipment 1A may include, in addition to the resistance for detection, the first terminal pair, and the second terminal pair which are connected to each of the wires 23U, 23V, and 23W shown in FIG. 6, the resistance for detection, the first terminal pair, and the second terminal pair which are connected to the wire 24 of each phase shown in FIG. 8.

Further, the electronic equipment 1A may not include the resistance for detection, the first terminal pair, and the second terminal pair which are shown in FIG. 6, but may include only the resistance for detection, the first terminal pair, and the second terminal pair which are connected to the wire 24 of each phase shown in FIG. 8.

Also in any electronic equipment 1A, the sensor circuit 3 or 3A subtracts the noise components inputted thereto via the second terminal pairs from the detection signals inputted thereto via the first terminal pairs. As a result, the sensor circuit 3 or 3A can remove an error caused by the noise component from the measured value of the current or voltage in each wire which the electronic equipment 1A includes.

FIG. 9 is a block diagram showing the configuration of a variant (2) of the electronic equipment 1A. In a sensor circuit 3 or 3A, a resistance for detection may be a series resistance circuit in which a first resistor for detection and a second resistor for detection are connected in series with respect to a wire 25 which connects between a lower arm switching element for each phase and a negative terminal (-) of a DC power supply, as shown in FIG. 9.

A first terminal pair 31U is constituted by a terminal wire connected to a terminal 43U in the first resistor for detection R_{S_1_U} of the series resistance circuit, the terminal 40U being opposite to the second resistor for detection R_{S_2_U}, and a terminal wire connected to a terminal 44U in the second resistor for detection R_{S_2_U} of the series resistance circuit, the terminal 44U being opposite to the first resistor for detection R_{S_1_U}. A second terminal pair 32U is constituted by two terminal wires which are connected to each other and short-circuited at a terminal 45U where the first resistor for detection R_{S_1_U} and the second resistor for detection R_{S_2_U} are connected.

The same goes for a first terminal pair 31V, a second terminal pair 32V, a first terminal pair 31W, and a second terminal pair 32W whose representations are omitted in FIG. 9. More specifically, the first terminal pair 31V is constituted by a terminal wire connected to a terminal 43V in a first resistor for detection R_{S_1_V} of a series resistance circuit, the terminal 40V being opposite to a second resistor for detection R_{S_2_V}, and a terminal wire connected to a terminal 44V in the second resistor for detection R_{S_2_V} of the series resistance circuit, the terminal 44V being opposite to the first resistor for detection R_{S_1_V}. The second terminal pair 32V is constituted by two terminal wires which are connected to each other and short-circuited at a terminal 45V where the first resistor for detection R_{S_1_V} and the second resistor for detection R_{S_2_V} are connected.

The first terminal pair 31W is constituted by a terminal wire connected to a terminal 43W in a first resistor for detection R_{S_1_W} of a series resistance circuit, the terminal 40W being opposite to a second resistor for detection R_{S_2_W}, and a terminal wire connected to a terminal 44W in the second resistor for detection R_{S_2_W} of the series resistance circuit, the terminal 44W being opposite to the first resistor for detection R_{S_1_W}. The second terminal pair 32W is constituted by two terminal wires which are connected to each other and short-circuited at a terminal 45W where the first resistor for detection R_{S_1_W} and the second resistor for detection R_{S_2_W} are connected.

A sensing section 33B subtracts detection signals inputted via the second terminal pairs 32U, 32V, and 32W and each containing only a noise component from detection signals of current values inputted thereto via the first terminal pairs 31U, 31V, and 31W and each containing the noise component, thereby removing the noise component (common mode noise component) in a wire 25 of each phase, and measures the current value in the wire 25 of each phase from which the noise component is removed.

In FIGS. 7, 8, and 9, the first terminal pair 31U and the second terminal pair 32U are equal in wire length of the terminal wire to each other. The first terminal pair 31V and the second terminal pair 32V are equal in wire length of the terminal wire to each other. The first terminal pair 31W and the second terminal pair 32W are equal in wire length of the terminal wire to each other. For example, in a case where the first terminal pair 31U is constituted by a terminal wire (1) which connects the terminal 34U and the positive terminal (+) of the amplification circuit 3311, and a terminal wire (2) which connects the terminal 35U and the negative terminal (-) of the amplification circuit 3311, and the second terminal pair 32U is constituted by a terminal wire (3) and a terminal wire (4) which are short-circuited by the terminal 36U, the terminal wires (1) to (4) equal in wire length to each other. Between the same phases and between different phases, the wire lengths of the terminal wires which constitute the first terminal pair and the second terminal pair are equal to each other.

The electronic equipment 1A may include, in addition to the resistance for detection, the first terminal pair, and the second terminal pair which are connected to each of the wires 23U, 23V, and 23W shown in FIG. 6, the resistance for detection, the first terminal pair, and the second terminal pair which are connected to the wire 25 of each phase shown in FIG. 9.

Instead, the electronic equipment 1A may include, in addition to the resistance for detection, the first terminal pair, and the second terminal pair which are connected to each of the wires 23U, 23V, and 23W shown in FIG. 6, the resistance for detection, the first terminal pair, and the second terminal pair which are connected to the wire 24 of each phase shown in FIG. 8, and may further include the resistance for detection, the first terminal pair, and the second terminal pair which are connected to the wire 25 of each phase shown in FIG. 9.

Instead, the electronic equipment 1A may include only the resistance for detection, the first terminal pair, and the second terminal pair which are connected to the wire 24 of each phase shown in FIG. 9.

Also in any electronic equipment 1A, the sensor circuit 3 or 3A subtracts the noise components inputted thereto via the second terminal pairs from the detection signals inputted thereto via the first terminal pairs. As a result, the sensor circuit 3 or 3A can remove the error caused by the noise component from the measured value of the current or voltage in each wire which the electronic equipment 1A includes.

Further, the sensor circuit 3 or 3A does not have to have the resistance for detection, the first terminal pair, and the second terminal pair for each of the wires of all the phases which are the wires 23U, 23V, and 23W, and, for example, the resistance for detection, the first terminal pair, and the second terminal pair may be disposed for each of two arbitrary phases out of the three phases.

In the sensor circuit 3 or 3A, the resistance for detection is not limited to the one constituted by the two resistors: the first resistor for detection R_{S_1} and the second resistor for detection R_{S_2}, and may be a single resistive element or a resistance circuit which is a combination of three or more resistive elements.

Further, in a case where the electronic equipment 1A includes multiple circuit sections 2A, the sensor circuit 3 or 3A may include a resistance for detection, a first terminal pair, and a second terminal pair for each of the multiple circuit sections 2A. In this case, the sensor circuit 3 or 3A can simultaneously perform measurements on the multiple circuit sections 2A.

Further, the sensing section 33B may be a discrete part independent of the control unit 4A, or the sensing section 33B and the control unit 4A may be a single integrated circuit (IC).

As mentioned above, the electronic equipment 1A according to Embodiment 2 includes: the sensor circuit 3 or 3A; the wires to each of which the resistance for detection is connected; the three-phase inverter circuit 21A which is a drive circuit; and the three-phase motor 22A which is a load circuit connected to the drive circuit by the wires. The sensor circuit 3A subtracts the noise components inputted thereto via the second terminal pairs from the detection signals inputted thereto via the first terminal pairs, thereby being able to remove the error caused by the noise component from the measured value of the current or voltage in each of the wires. As a result, the electronic equipment 1A can perform control of, for example, an operation using the measured value from which the error is removed.

In the electronic equipment 1A according to Embodiment 2, to the DC input positive terminal of the inverter circuit 21A is connected the positive terminal (+) of the DC power supply 21B, and to the DC input negative terminal is connected the negative terminal (-) of the DC power supply 21B. To the output wires of at least two phases, out of the output wires 23U, 23V, and 23W of the three phases in the inverter circuit 21A, is connected the series resistance circuit constituted by the first resistor for detection and the second resistor for detection. Each of the first terminal pairs 31U, 31V, and 31W is constituted by the terminal wires connected respectively to the terminals of the series resistance circuit. Each of the second terminal pairs 32U, 32V, and 32W is constituted by the terminal wires which are short-circuited to each other at the terminal where the first resistor for detection and the second resistor for detection in the series resistance circuit are connected. The sensor circuit 3 subtracts the noise components inputted thereto via the second terminal pairs 32U, 32V, and 32W, respectively, from the detection signals inputted thereto via the first terminal pairs 31U, 31V, and 31W, thereby being able to remove the error caused by the noise component from each of the measured values of the currents or voltages in the wires 23U, 23V, and 23W. As a result, the electronic equipment 1A can accurately perform feedback control of the driving of the three-phase motor 22A.

In the electronic equipment 1A according to Embodiment 2, to the DC input positive terminal of the inverter circuit 21A is connected the positive terminal (+) of the DC power supply 21B, and to the DC input negative terminal is connected the negative terminal (-) of the DC power supply 21B. Between the output wires of at least two phases, out of the output wires 23U, 23V, and 23W of the three phases in the inverter circuit 21A, and the negative terminal side wire 23A connected to the negative terminal (-) of the DC power supply 21B is connected the series resistance circuit in which the first resistor for detection and the second resistor for detection are connected in series. Each of the first terminal pairs 31U, 31V, and 31W is constituted by the terminal wires connected respectively to the terminals of the series resistance circuit. Each of the second terminal pairs 32U, 32V, and 32W is constituted by the terminal wires which are short-circuited to each other at the terminal where the first resistor for detection and the second resistor for detection in the series resistance circuit are connected. The sensor circuit 3A subtracts the noise components inputted thereto via the second terminal pairs 32U, 32V, and 32W, respectively, from the detection signals inputted thereto via the first terminal pairs 31U, 31V, and 31W, thereby being able to remove the error caused by the noise component from each of the measured values of the currents or voltages in the wires 23U, 23V, and 23W. As a result, the electronic equipment 1A can accurately perform feedback control of the driving of the three-phase motor 22A.

The electronic equipment 1A according to Embodiment 2 includes: the three-phase inverter circuit 21A in which the upper arm switching elements 211U, 211V, and 211W and the lower arm switching elements 212U, 212V, and 212W are connected in series; the DC power supply 21B whose positive terminal (+) is connected to the DC input positive terminal of the inverter circuit 21A, and whose negative terminal (-) is connected to the DC input negative terminal; and the sensor circuit 3 or 3A having the resistances for detection each of which is connected in series to one of the wires 24 which connect the upper arm switching elements 211U, 211V, and 211W and the positive terminal (+) of the DC power supply 21B, the first terminal pairs 31U, 31V, and 31W each of which is constituted by terminal wires connected respectively to the terminals of a resistance for detection, the second terminal pairs 32U, 32V, and 32W each of which is constituted by terminal wires short-circuited to each other at one terminal of a resistance for detection, and the sensing section 33B to measure the current or voltage in the wire 24 of each phase from which the noise component is removed, using the detection signals inputted thereto via the first terminal pairs 31U, 31V, and 31W and the detection signals inputted thereto via the second terminal pairs 32U, 32V, and 32W. The sensor circuit 3 or 3A subtracts the noise components inputted thereto via the second terminal pairs 32U, 32V, and 32W, respectively, from the detection signals inputted thereto via the first terminal pairs 31U, 31V, and 31W, thereby being able to remove the error caused by the noise component from the measured value of the current or voltage in the wire 24 of each phase.

The electronic equipment 1A according to Embodiment 2 includes: the three-phase inverter circuit 21A in which the upper arm switching elements 211U, 211V, and 211W and the lower arm switching elements 212U, 212V, and 212W are connected in series; the DC power supply 21B whose positive terminal (+) is connected to the DC input positive terminal of the inverter circuit 21A, and whose negative terminal (-) is connected to the DC input negative terminal; and the sensor circuit 3 or 3A having the resistances for detection each of which is connected in series to one of the wires 25 which connect the lower arm switching elements 212U, 212V, and 212W and the negative terminal (-) of the DC power supply 21B, the first terminal pairs 31U, 31V, and 31W each of which is constituted by terminal wires connected respectively to the terminals of a resistance for detection, the second terminal pairs 32U, 32V, and 32W each of which is constituted by terminal wires short-circuited to each other at one terminal of a resistance for detection, and the sensing section 33B to measure the current or voltage in the wire 25 of each phase from which the noise component is removed, using the detection signals inputted thereto via the first terminal pairs 31U, 31V, and 31W and the detection signals inputted thereto via the second terminal pairs 32U, 32V, and 32W. The sensor circuit 3 or 3A subtracts the noise components inputted thereto via the second terminal pairs 32U, 32V, and 32W, respectively, from the detection signals inputted thereto via the first terminal pairs 31U, 31V, and 31W, thereby being able to remove the error caused by the noise component from the measured value of the current or voltage in the wire 25 of each phase.

It is to be understood that a combination of embodiments can be made, a change can be made to an arbitrary component in each of the embodiments, or an arbitrary component in each of the embodiments can be omitted.

### INDUSTRIAL APPLICABILITY

The sensor circuit according to the present disclosure can be used in, for example, electronic equipment having a three-phase inverter circuit and a three-phase motor.

### REFERENCE SIGNS LIST

1 and 1A: Electronic equipment, 2 and 2A: Circuit section, 3 and 3A: Sensor circuit, 4 and 4A: Control unit, 21: Drive circuit, 21A: Inverter circuit, 21B: DC power supply, 22: Load circuit, 22A: Motor, 23, 23U, 23V, 23W, 24, and 25: Wire, 31, 31U, 31V, and 31W: First terminal pair, 32, 32U, 32V, and 32W: Second terminal pair, 33, 33A, and 33B: Sensing section (Sensing circuit), 34, 34U, 34V, 34W, 35, 35U, 35V, 35W, 36, 36U, 36V, 36W, 37, 37U, 37V, 37W, 38, 38U, 38V, 38W, 39, 39U, 39V, 39W, 40, 40U, 40V, 40W, 41, 41U, 41V, 41W, 42, 42U, 42V, 42W, 43, 43U, 43V, 43W, 44, 44U, 44V, 44W, 45U, 45V, 45W, 211U, 211V, and 211W: Upper arm switching element, 212U, 212V, and 212W: Lower arm switching element, 331: Signal measurement circuit, 332: Noise measurement circuit, 333 and 333A: Noise correction circuit, 3311 and 3321: Amplification circuit, 3331: Analog subtractor circuit, 3332 and 3333: AD converter, and 3334: Subtractor.

1. A sensor circuit to measure a current or voltage in a wire of electronic equipment having a circuit section in which a drive circuit and a load circuit are connected by one or multiple wires, the sensor circuit comprising:
a resistance for detection connected to the one or multiple wires;
a first terminal pair comprised of terminal wires connected respectively to terminals of the resistance for detection;
a second terminal pair comprised of terminal wires short-circuited to each other at one terminal of the resistance for detection; and
a sensing circuit to measure the current or voltage from which a noise component is removed using a detection signal inputted thereto via the first terminal pair and a detection signal inputted thereto via the second terminal pair.

2. The sensor circuit according to claim 1, wherein the sensing circuit includes:
a signal measurement circuit to amplify the detection signal inputted thereto via the first terminal pair;
a noise measurement circuit to amplify the detection signal inputted thereto via the second terminal pair; and
a noise correction circuit to subtract a value of the detection signal amplified by the noise measurement circuit from a value of the detection signal amplified by the signal measurement circuit, and to perform output,
wherein the signal measurement circuit and the noise measurement circuit are the same in circuit configuration as each other.

3. The sensor circuit according to claim 1, wherein
the resistance for detection is a series resistance circuit comprised of a first resistor for detection and a second resistor for detection which are connected in series in the wire,
the first terminal pair is comprised of terminal wires connected respectively to terminals of the series resistance circuit, and
the second terminal pair is comprised of terminal wires short-circuited to each other at a terminal where the first resistor for detection and the second resistor for detection in the series resistance circuit are connected to each other.

4. The sensor circuit according to claim 1, wherein
the resistance for detection is a series resistance circuit comprised of a first resistor for detection and a second resistor for detection which are connected in series between two wires out of the multiple wires which connect the drive circuit and the load circuit,
the first terminal pair is comprised of terminal wires connected respectively to terminals of the series resistance circuit, and
the second terminal pair is comprised of terminal wires short-circuited to each other at a terminal where the first resistor for detection and the second resistor for detection in the series resistance circuit are connected.

5. The sensor circuit according to claim 3, wherein the first resistor for detection and the second resistor for detection are the same in resistance value as each other.

6. The sensor circuit according to claim 4, wherein the first resistor for detection and the second resistor for detection are the same in resistance value as each other.

7. The sensor circuit according to claim 1, wherein the first terminal pair and the second terminal pair are the same in wire length of terminal wires as each other.

8. The sensor circuit according to claim 2, wherein the first terminal pair and the second terminal pair are the same in wire length of terminal wires as each other.

9. The sensor circuit according to claim 3, wherein the first terminal pair and the second terminal pair are the same in wire length of terminal wires as each other.

10. The sensor circuit according to claim 4, wherein the first terminal pair and the second terminal pair are the same in wire length of terminal wires as each other.

11. Electronic equipment comprising:
the sensor circuit according to claim 1;
the wires to which the resistance for detection is connected;
the drive circuit; and
the load circuit connected to the drive circuit by the wires.

12. The electronic equipment according to claim 11, wherein
the drive circuit includes a three-phase inverter circuit and a DC power supply,
a positive terminal of the DC power supply is connected to a DC input positive terminal of the inverter circuit,
a negative terminal of the DC power supply is connected to a DC input negative terminal of the inverter circuit,
out of output wires of three phases in the inverter circuit, a series resistance circuit in which a first resistor for detection and a second resistor for detection are connected in series is connected to output wires of at least two phases,
the first terminal pair is comprised of terminal wires connected respectively to terminals of the series resistance circuit, and
the second terminal pair is comprised of terminal wires short-circuited to each other at a terminal where the first resistor for detection and the second resistor for detection in the series resistance circuit are connected.

13. The electronic equipment according to claim 11, wherein
the drive circuit includes a three-phase inverter circuit and a DC power supply,
a positive terminal of the DC power supply is connected to a DC input positive terminal of the inverter circuit,
a negative terminal of the DC power supply is connected to a DC input negative terminal of the inverter circuit,
out of output wires of three phases in the inverter circuit, a series resistance circuit in which a first resistor for detection and a second resistor for detection are connected in series is connected between output wires of at least two phases and a negative terminal side wire connected to the negative terminal of the DC power supply,
the first terminal pair is comprised of terminal wires connected respectively to terminals of the series resistance circuit, and
the second terminal pair is comprised of terminal wires short-circuited to each other at a terminal where the first resistor for detection and the second resistor for detection in the series resistance circuit are connected.

14. Electronic equipment comprising:
a three-phase inverter circuit in which upper arm switching elements and lower arm switching elements are connected in series;
a DC power supply whose positive terminal is connected to a DC input positive terminal of the inverter circuit, and whose negative terminal is connected to a DC input negative terminal of the inverter circuit; and
a sensor circuit having resistances for detection each of which is connected in series to one of wires which connect the upper arm switching elements and the positive terminal of the DC power supply, first terminal pairs each of which is comprised of terminal wires connected respectively to terminals of a resistance for detection, second terminal pairs each of which is comprised of terminal wires short-circuited to each other at one terminal of a resistance for detection, and a sensing circuit to measure currents or voltages in wires from which noise components are removed, using detection signals inputted thereto via the first terminal pairs and detection signals inputted thereto via the second terminal pairs.

15. Electronic equipment comprising:
a three-phase inverter circuit in which upper arm switching elements and lower arm switching elements are connected in series;
a DC power supply whose positive terminal is connected to a DC input positive terminal of the inverter circuit, and whose negative terminal is connected to a DC input negative terminal of the inverter circuit; and
a sensor circuit having resistances for detection each of which is connected in series to one of wires which connect the lower arm switching elements and the negative terminal of the DC power supply, first terminal pairs each of which is comprised of terminal wires connected respectively to terminals of a resistance for detection, second terminal pairs each of which is comprised of terminal wires short-circuited to each other at one terminal of a resistance for detection, and a sensing circuit to measure currents or voltages in wires from which noise components are removed, using detection signals inputted thereto via the first terminal pairs and detection signals inputted thereto via the second terminal pairs.
